(19) United States
(12) Patent Application Publication
(10) Pub. No.: US 2010/0259433 A1
(43) Pub. Date: Oct. 14, 2010

(54) Signal Processing System

(75) Inventors: Andrew Mark Bishop, Hertfordshire (GB); Chiok Keng Leong, Hertfordshire (GB)

Correspondence Address: KENYON & KENYON LLP, ONE BROADWAY, NEW YORK, NY, 10004, US

(73) Assignee: ASTRIUM LIMITED, STEVENAGE HERTFORDSHIRE (GB)

(21) Appl. No.: 12/086,544

(22) PCT Filed: May 6, 2008
(86) PCT No.: PCT/GB2008/050329

§ 371 Date: Jun. 12, 2008

(30) Foreign Application Priority Data
May 10, 2007 (EP) 07270023.0
May 10, 2007 (GB) 0708940.2

(51) Int. Cl. H03M 1/12

(52) U.S. Cl. 341/155

(57) ABSTRACT

A digital signal processor that is required to process a large number of narrowband analog input or output signals. Analog processing is performed to combine multiple analog signals together (with non-overlapping frequency bands) into a composite signal which is fed to a single analog to digital converter. These signals come from different sources and would in a conventional implementation use individual converters. Analog signal processing is used outside of the digital signal processor and digital processing is used inside to enable the original analog signals to be reconstructed in the digital domain in the same format as if individual converters have been used. A similar technique can be applied to digital to analog conversion interfaces where a digital combining operation is performed to combine digital sub-band signals into a single composite signal, prior to input to a single digital-to-analog (DAC) converter for conversion to the analog domain and subsequently to an analog splitter device for separation into a plurality of analog signals. Hence, the technique can be implemented in both transmitter and receiver systems.

### RELATED APPLICATION INFORMATION

This application is a United States National Phase Patent Application of International Patent Application No. PCT/GB2008/050329 which was filed on May 6, 2008, and claims priority to British Patent Application No. 0708940.2, filed on May 10, 2007, and claims priority to European Patent Application No. 07270023.0, filed on May 10, 2007, the disclosures of each of which are incorporated herein by reference.

### FIELD OF THE INVENTION

The present invention relates to signal processing techniques and, in particular, to the analog interfaces to digital signal processing systems.

### BACKGROUND INFORMATION

Digital signal processing is the basis of many areas of technology, from communications systems to multimedia PCs. The processing of signals may be carried out in the digital domain because digital processing is fast, accurate and reliable. The introduction of digital signal processing chips—specialized microprocessors with architectures designed specifically for the types of operations required in digital signal processing, made it possible for the techniques to be used in a much wider range of applications. In most cases, the input signals of interest are initially in the form of an analog current or voltage and must be converted into digital form before digital signal processing techniques can be applied. Similarly, the output signals from a digital signal processor are digital values that frequently require conversion back to analog form before they can be used or analyzed further. Such conversion of signals to and from the digital domain is typically performed by analog to digital (ND) and digital to analog (D/A) converters which form an essential link in the signal processing pathway at the interface between the analog and digital domains.

Analog to digital (ADC) and Digital to Analog (DAC) converters range in size, complexity, and accuracy or resolution, where each of these factors depends upon the particular needs of the underlying application. Different architectures are suited to different needs. Serial analog-to-digital architecture offers the widest range of performance in analog-to-digital conversion, from low power and low resolution to quantizations with very high resolutions. Parallel analog-to-digital architecture provides the fastest quantization rate per analog signal. The pipelined analog-to-digital converter has become a popular ADC architecture for use in high-speed applications such as imaging and fast Ethernets. Although, advances in ADC and DAC technology have increased the speed and accuracy of ADC and DAC converters, this is frequently at the expense of high component count and high power consumption.

Conventional analog interfaces to the digital signal processors used in receiver and transmitter systems will now be described with reference to FIGS. 1a and 1b. FIG. 1a shows a block diagram of a receiver system 10 of a satellite but the system is also applicable to the receiver of a base station. The RF front end may include a plurality of N antenna elements 12₁ . . . 12_{N}, arranged to receive transmitted RF signals, each element coupled to a low noise amplifier (LNA) (not shown), where the received RF signal is amplified. Each amplified element signal is fed to a down conversion module 14₁ . . . 14_{N}, where conversion to an intermediate frequency (IF) or baseband is performed using respective signals from a local oscillator (not shown). Due to the use of a common local oscillator frequency f_{LO}, the respective IF or baseband signals S_{IF1} . . . S_{IFn} produced by the downconverters 14₁ . . . 14_{N} all occupy the same frequency band. Each IF signal S_{IF1} . . . S_{IFN} is then converted into a digital signal using a corresponding set of N analog-to-digital converters 16₁ . . . 16_{N} and fed to a digital signal processor 18 where the appropriate processing such as channnelization, beam forming and channel combining etc takes place. The M output signals S_{D1} . . . S_{DM} are subsequently converted to analog form by feeding to a corresponding set of M digital-to-analog converters 20₁ . . . 20_{M} and are upconverted to an RF frequency in a set of upconverter modules 22₁ . . . 22_{M} and fed to one or more downlink antennae 24₁ . . . 24_{M}.

FIG. 1b shows a block diagram of a conventional transmitter system 30 of a subscriber unit. Transmitter system includes a down conversion module 32 where conversion of one or more RF transmit signal S_{RF} to an intermediate frequency (IF) is performed using respective signals from a local oscillator (not shown). The IF signal(s) S_{IF} is then converted into a digital signal S_{D} by ND converter 34 and fed into a digital signal processing block 36 where techniques such as channel combining, beam forming and channnelization is carried out. The plurality, N of digital channel signals S_{D1} . . . S_{DN} at the output of the DSP 36 are converted to N analog signals in a corresponding set of N D/A converters 38₁ . . . 38_{N} and upconverted to IF in a set of up converter modules 40₁ . . . 40_{N} before being transmitted by the respective antenna elements 42₁ . . . 42_{N}.

Hence, in the conventional receiver and transmitter systems described above, each of the down-converted IF or baseband frequency signals from the receiver is processed by a separate analog to digital converter, while in the transmitter each of the digitized signals derived from a signal to be transmitted is processed by a separate digital to analog (DAC) converter. In the implementation of large signal processing systems such as, for example, on-board satellite communications systems, this configuration may involve the use of many hundreds and potentially thousands of converters. The power consumption associated with such multiple converters can amount to a significant proportion of the total power consumption of the system.

Over the past decade, although developments in ADC/DAC technology have resulted in higher-performance devices with typical increases in processed bandwidth by a factor of ten, power consumption has remained relatively high. Over the same period, developments in integrated circuit technology have resulted in reductions in power consumption by a factor of ten in addition to an increase in bandwidth by the same factor. This means that the power consumption of the ADC/DAC has increased as a proportion of the total power consumption and can frequently account for as much as 30% of the total power in many systems. In addition, the complexity of the circuitry involved is undesirable.

Multiple lower bandwidth ADCs may be used to digitize higher bandwidth signals. For example, if an input analog signal at 100 MHz is to be digitized but only ADCs that operate at 50 MHz are available, it is possible to use two ADCs together to provide a 100 MHz sampling rate by offsetting the sampling time so that each ADC samples at times that are 1/100 MHz apart producing alternate samples that make up the complete data stream. Subsequent digital processing is required to reconstruct the original signal by interleaving the data samples from the two ADCs and optionally to remove any errors introduced by using two different devices. Some commercial ADCs contain multiple time-interleaved ADC functions within them so that they can cover a wide bandwidth with many, simple, low bandwidth functional blocks.

A single ADC may be shared between two or more signals by time multiplexing the converter. However, although the overall number of converters required at the interface is reduced, such converters and the associated multiplexing components are complicated and less efficient as the sampling rate that may be used with each multiplexed signal is reduced.

Down-conversion by band-pass sampling is sometimes used to achieve digitization closer to the antenna within the receiver but has its limitations. The analog bandwidth of the ADC input must be sufficient to handle the frequency band of the signal that is being sampled and the center frequency must be matched to the sampling rate of the ADC to ensure that the signal can be captured successfully. The signal that is being sampled must also be sufficiently band-limited so that the sampling process does not add too much noise due to aliasing. The impact of clock jitter on the sampling clock in the ADC increases with frequency and is much more significant at these RF frequencies than at baseband. The limitations on the center frequency and bandwidth mean that it is more difficult to design a generic digital signal processor since the sampling rate typically needs to be selected for each application.

It is an object of the present invention to provide a signal processing system that, at least partially, ameliorates one or more of the problems described above.

It is another object of the present invention to provide a signal processing system having analog and/or digital interfaces with reduced power consumption.

It is a further object of the present invention to reduce the complexity of digital signal processing analog interfaces.

### SUMMARY OF THE INVENTION

The present invention resides in a signal processing system including a plurality of input channels for receiving signals, each channel being adapted to handle signals associated with a predetermined frequency sub-band, a summation system adapted to combine signals from each channel together to form a composite signal; a converter arrangement adapted to convert the composite signal from the analog to the digital domain or from the digital to the analog domain, and a processing arrangement adapted to process the output from the converter arrangement and to derive a plurality of output signals therefrom.

In a first exemplary embodiment, each input channel is adapted to receive signals from different elements of a multi-element antenna and the output signals derived by the processing arrangement may be combined by beamforming. The summation system may include an analog combiner adapted to sum the channel signals to form a single composite wideband signal and the converter arrangement includes a single analog to digital converter adapted to convert the composite wideband signal for subsequent digital signal processing. By combining multiple analog signals together, a single ADC may be used for conversion to the digital domain and the individual signals may be isolated as part of the digital processing which is faster and more efficient. This is advantageous in that there are fewer connections into the digital signal processor and due to the inherent repeatability of digital processing, overall processing efficiency is improved.

In a second exemplary embodiment, the processing arrangement is adapted to derive output signals to be transmitted by different elements of a multi-element antenna and the input channels may be adapted to receive digital signals generated by beamforming. The summation system may include a digital combiner adapted to sum the digital channel signals to form a single composite wideband signal and the converter arrangement includes a single digital to analog converter adapted to convert the composite wideband signal for subsequent processing in the analog domain. Again, by combining multiple digital signals together, a single DAC may be used for conversion to the analog domain, in contrast with the conventional transmitter systems described above where each of the digitized signals derived from a signal to be transmitted is processed by a separate digital to analog (DAC) converter.

In both of these embodiments, the signals that are received from or are to be transmitted from different elements of the multi-element antenna are associated with predetermined frequency sub-bands of identical bandwidth and center frequency.

In the first exemplary embodiment, the processing arrangement includes a digital demultiplexer adapted to divide the converted composite wideband signal into a plurality of digital signals, each containing a representation of one of the input sub-band signals. In particular, a frequency demultiplexing operation is-may be performed to separate the composite channel signal into a plurality of sub-band signals each with a fraction 1/n of the composite sample rate. The system may further include a plurality of down-converter modules adapted to down-convert the signals in each input channel from RF to a baseband frequency, each down-converter module being arranged to provide a different frequency local oscillator frequency to its associated mixer.

In the second exemplary embodiment, the processing arrangement includes an analog splitting arrangement adapted to divide the converted composite wideband signal to a plurality of analog sub-band signals. The system may further include a plurality of up-converter modules adapted to up-convert the signals in each output channel from baseband frequency to RF, each up-converter module being arranged to provide a different frequency local oscillator frequency to its associated mixer.

In both exemplary embodiments, the converter arrangement may includes a plurality of converters, each adapted to handle signals associated with a particular subset of antenna elements.

### BRIEF DESCRIPTION OF THE DRAWINGS

FIG. 1a is a block diagram representation of a conventional receiver system used in a satellite communications system.

FIG. 1b is a block diagram of a conventional transmitter system used in a subscriber unit.

FIG. 2 is a schematic representation of an analog interface to a digital signal processor according to an embodiment of the present invention as incorporated in the receiver of a phased array antenna for use in a satellite communications system.

FIG. 3, is a schematic representation of a digital-to-analog interface according to another embodiment of the present invention as incorporated in the transmitter of an antenna system.

### DETAILED DESCRIPTION

Exemplary embodiments of the present invention will now be described in more detail, by way of example only, with reference to the accompanying drawings.

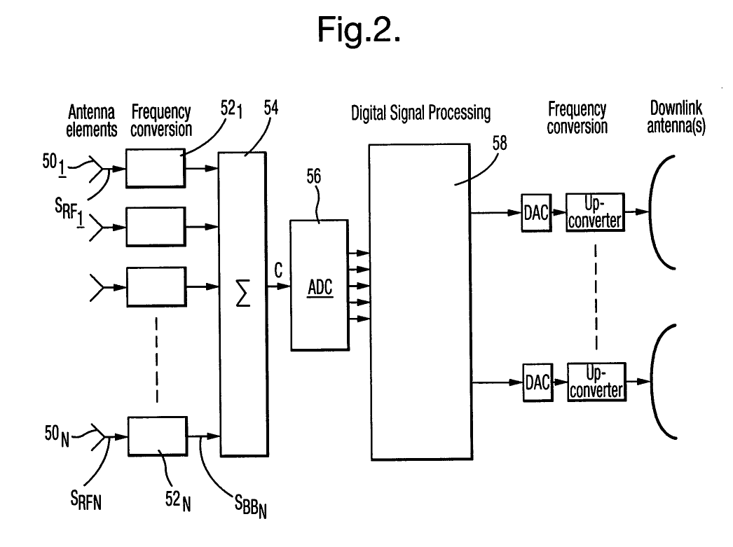

A first embodiment of the invention as incorporated in a phased array antenna for use in a satellite communications system will now be described with reference to FIG. 2. A phased array receiving system includes a plurality, N, of antenna elements 50₁ . . . 50_{N} arranged to form a two dimensional antenna array. For simplicity, four such elements are illustrated in FIG. 2 but it should be appreciated that N may include any number depending on the system requirements. Each of the four antenna elements of the array is arranged to receive a different radio frequency (RF) signal of a particular frequency sub-band (S_{RF1} . . . S_{RF4}), each sub-band having equal bandwidth of 40 MHz (as typically used in mobile communications) and to convert it to a corresponding electrical signal. Each of the four sub-band signals is amplified, filtered and passed to a series of four down-converters 52₁ . . . 52₄, where down-conversion from RF to a baseband frequency is carried out. In this instance, each down-converter module 52₁ . . . 52₄, is arranged to provide a different frequency local oscillator frequency LO_{f1} . . . LO_{f4}to its mixer, so that the respective baseband signals S_{BB1} . . . S_{BB4} produced by the mixers each occupy a different frequency sub-band (BB₁ . . . BB₄). The four down-converted sub-band signals S_{BB1} . . . S_{BB4} are then summed together in an analog combiner 54 to form a single composite wideband signal C=S_{BBf1}+S_{BBf2} . . . +S_{BBf4} having a combined bandwidth of at least 160 MHz. This composite signal C is then converted to a digital signal using a single analog-to-digital (ADC) converter 56. By Nyquist's theorem, a sampling rate of at least 320 MHz must be used by the ADC 56 in order to process the combined signal. The resulting digital signal is fed to the digital signal processor (DSP) 58.

Within the digital signal processor 58, the signal may be processed using one of several different algorithms depending on the particular application or system requirements. The simplest digital processing that could be performed would be an N-way de-multiplexer so that a set of N separate digital signals are produced, each containing a representation of one of the input sub-band signals. Alternatively, each of the input sub-bands may be divided into a series of narrower frequency channels and beam-forming processing performed on signals from all antenna elements so as to form separate beams with different directional vectors to accommodate various communication signals arriving from different directions or different transmitting devices. It should be understood that various processing algorithms may be applied within the digital signal processor depending on the particular system requirements and this aspect does not fall within the scope of the present invention. Once within the digital domain, the signal processing is repeatable, well defined and inherently does not involve any significant extra processing for a single input of N times the bandwidth, in comparison to N individual inputs.

Hence by combining multiple analog signals together, a single ADC may be used for conversion to the digital domain and the individual signals may be isolated as part of the digital processing which is faster and more efficient. This is advantageous in that there are fewer connections into the digital signal processor and due to the inherent repeatability of digital processing, overall processing efficiency is improved. The technique does require a different LO frequency for each sub-band during down-conversion which increases frequency dependent effects (e.g., amplitude and phase errors) and necessitates a higher sampling rate in the ADC than would be required with multiple lower bandwidth signals. However, the overall benefits offered by the reduction in the number of analog to digital converters that are required more than compensates for these effects in most applications.

It should also be appreciated that the antenna array may include a plurality of sub-arrays of elements, with an individual ADC being used to convert the composite signal from each sub-array of elements.

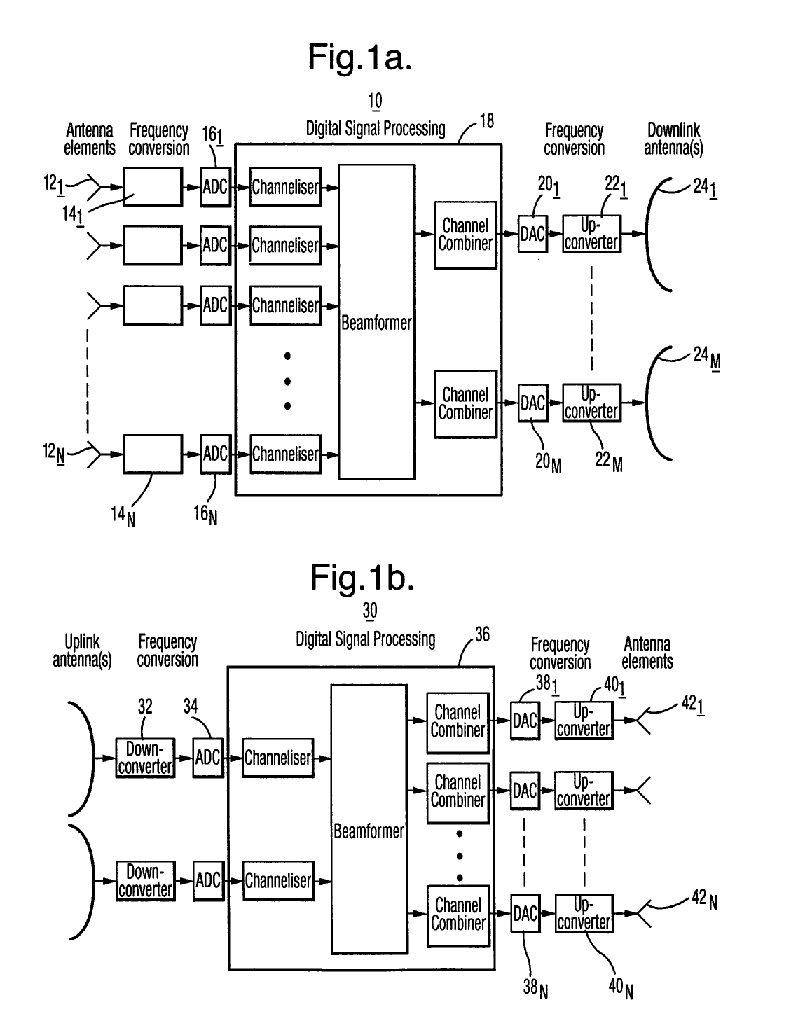

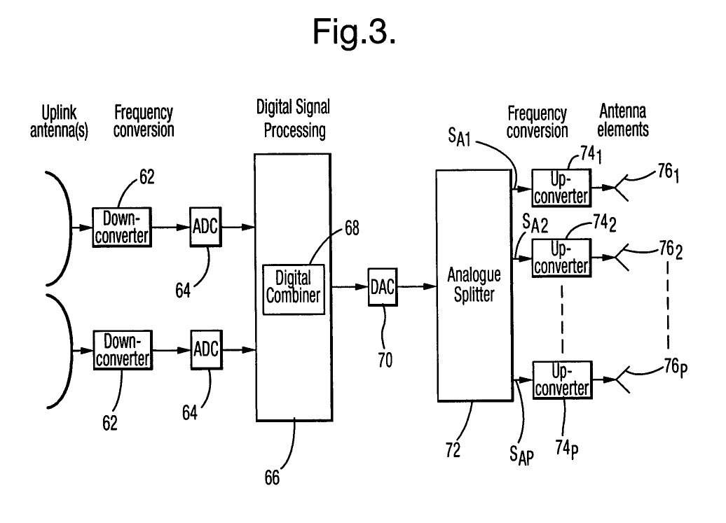

A similar technique can be applied to digital to analog conversion interfaces as will now be described with reference to FIG. 3. As described earlier with reference to FIG. 1b, one or more input signals S to be transmitted are down converted 62 to IF, converted to P digital signals by A/D converters 64 and fed into a digital signal processing block 66 for processing. Again, various algorithms may be applied in the digital signal processor 66 depending on the system requirements. In the simplest case, a digital combining operation 68, such as frequency multiplexing, may be performed to combine the P sub-band signals S_{D1}, S_{D2} . . . , S_{DP} into a single composite signal C=S S_{D1}+S_{D2+} . . . +S_{DP} with P times the sample rate. The composite digital signal is fed to a single digital-to-analog (DAC) converter 70 for conversion to the analog domain and to an analog splitter device 72 for separation into P analog signals S_{A1}, S_{A2} . . . , S_{AP}. The P analog signals S_{A1}, S_{A2} . . . , S_{AP} are fed to a plurality of up-converter modules 74₁. . . 74_{P} for up-conversion to the applicable transmit carrier RF frequency within a mixer by mixing with a signal provided by a local oscillator.

The resulting set of P RF signals (i.e., RF₁, RF₂. . . , RF_{P}) are then amplified by respective amplifiers (not shown) and transmitted by respective antennae elements 76₁. . . 76_{P}.

Although in the described embodiment, sub-bands of equal bandwidth are used, it is also contemplated that sub-bands of differing bandwidths may also be used. It should also be appreciated that the technique of the present invention is relevant to any application that would normally require the use of a large number of low bandwidth converters as these may be replaced with a small number of larger bandwidth converters and is applicable to any band-limited input signals. For example, the technique could be applied to stereo audio signals having two baseband signals. However, frequency shifting of one of the signals would be required so that there is no overlap within the same baseband frequency range. The two signals can then be added and the composite signal fed to an ADC that operates at twice the sampling rate that would be needed for a single one of the signals. In all applications where n signals are combined, at least n-1 of the signals must be frequency shifted.

In summary, the invention relates to the implementation of a digital signal processor that is required to process a large number of narrowband analog input or output signals. The invention is advantageous in that analog processing is performed to combine multiple analog signals together (with non-overlapping frequency bands) into a composite signal which is fed to a single analog to digital converter. Those signals come from different sources and would in a conventional implementation use individual converters. Analog signal processing is used outside of the digital signal processor and digital processing is used inside to enable the original analog signals to be reconstructed in the digital domain in the same format as if individual converters have been used.

1-16. (canceled)

17. A signal processing system, comprising:
a plurality of input channels for receiving signals, each channel being adapted to handle signals associated with a predetermined frequency sub-band;
a summation system adapted to combine signals from each channel together to form a composite signal;
converter means adapted to convert the composite signal from one of the analog to the digital domain and the digital to the analog domain; and
processing means adapted to process the output from the converter means and to derive a plurality of output signals therefrom.

18. A signal processing system according to claim 17, wherein each input channel is adapted to receive signals from different elements of a multi-element antenna.

19. A signal processing system according to claim 17, wherein the output signals derived by the processing means are combined by beamforming.

20. A signal processing system according to claim 17, wherein the processing means is adapted to derive output signals to be transmitted by different elements of a multi-element antenna.

21. A signal processing system according to claim 17, wherein the input channels are adapted to receive digital signals generated by beamforming.

22. A signal processing system according to claim 18, wherein the signals that are received from different elements of the multi-element antenna are associated with predetermined frequency sub-bands of identical bandwidth and center frequency.

23. A signal processing system according to claim 20, wherein the signals to be transmitted by different elements of the multi-element antenna are associated with predetermined frequency sub-bands of identical bandwidth and center frequency.

24. A signal processing system according to claim 17, wherein the summation system includes an analog combiner adapted to sum the signals from each channel to form a single composite wideband signal, and wherein the converter means includes a single analog to digital converter adapted to convert the composite wideband signal for subsequent digital signal processing.

25. A signal processing system according to claim 17, wherein the summation system includes a digital combiner adapted to sum the digital signals from each channel to form a single composite wideband signal, and wherein the converter means includes a single digital to analog converter adapted to convert the composite wideband signal for subsequent processing in the analog domain.

26. A signal processing system according to claim 18, wherein the processing means includes a digital demultiplexer adapted to divide the converted composite wideband signal into a plurality of digital signals, each containing a representation of one of the input sub-band signals.

27. A signal processing system according to claim 20, wherein the processing means includes analog splitting means adapted to divide the converted composite wideband signal to a plurality of analog sub-band signals.

28. A signal processing system according to claim 18, further comprising:
a plurality of down-converter modules adapted to down-convert the signals in each input channel from RF to a baseband frequency, wherein each down-converter module is arranged to provide a different frequency local oscillator frequency to its associated mixer.

29. A signal processing system according to claim 20, further comprising:
a plurality of up-converter modules adapted to up-convert the signals in each output channel from baseband frequency to RF, wherein each up-converter module is arranged to provide a different frequency local oscillator frequency to its associated mixer.

30. A signal processing system according to claim 26, wherein the digital processing is adapted to perform a frequency demultiplexing operation to separate the composite channel signal into a plurality of sub-band signals each with a fraction 1/n of the composite sample rate.

31. A signal processing system according to claim 25, wherein the digital combiner is adapted to perform a frequency multiplexing operation to combine the channel sub-band signals into a single composite signal with n times the sample rate.

32. A signal processing system according to claim 18, wherein the converter means includes a plurality of converters, each adapted to handle signals associated with a particular subset of antenna elements.

33. A signal processing system, comprising:
a plurality of input channels for receiving signals, each channel being adapted to handle signals associated with a predetermined frequency sub-band;
a summation system adapted to combine signals from each channel together to form a composite signal;
a converter arrangement adapted to convert the composite signal from one of the analog to the digital domain and the digital to the analog domain; and
a processing arrangement adapted to process the output from the converter arrangement and to derive a plurality of output signals therefrom.
